(19) United States
(12) Patent Application Publication
(10) Pub. No.: US 2005/0106813 A1
(43) Pub. Date: May 19, 2005

(54) Method of manufacturing flash memory device

(76) Inventors: Seong Cheol Lee, Gyeonggi-do (KR); Sang Hyon Kwak, Gyeonggi-do (KR); Sang Wook Park, Seoul (KR)

Correspondence Address: MARSHALL, GERSTEIN & BORUN LLP, 6300 SEARS TOWER, 233 S. WACKER DRIVE, CHICAGO, IL, 60606, US

(21) Appl. No.: 10/745,165

(22) Filed: Dec. 23, 2003

(30) Foreign Application Priority Data
Nov. 19, 2003 (KR) 2003-81958

(51) Int. Cl. H01L 21/336; H01L 21/8234; H01L 21/461

(52) U.S. Cl. 438/257; 438/756; 438/757; 438/275

(57) ABSTRACT

Provided is a method of manufacturing a flash memory device. In a flash memory device using a self-aligned shallow trench isolation scheme, a buffer oxide layer is formed between a first polysilicon layer and a nitride layer. After a polishing process for forming a field oxide film is performed, a buffer oxide layer is used as an etch-prevention layer in the process of stripping the nitride layer and the buffer oxide layer is stripped in a cleaning process before a second polysilicon layer is deposited. It is thus possible not only to prevent phosphorous ions contained in an H₃PO₄ solution used in the process of stripping the nitride layer from diffusing into the grain boundary of the first polysilicon layer, but also to reduce the time when the first polysilicon layer is exposed to a HF cleaner used in the cleaning process before the second polysilicon layer is deposited. Therefore, the present invention has effects that it can enhance the properties of a gate oxide layer and a gate electrode by minimizing an attack of a fluorine radical contained in the HF cleaner against the first polysilicon layer.

### BACKGROUND

1. Field of the Invention

The present invention relates to a method of manufacturing a flash memory device and, more specifically, to a method of manufacturing a flash memory device that can enhance the properties of a gate oxide layer and a gate electrode in a flash memory device using a self-aligned shallow trench isolation (hereinafter, referred to as “SA-STI”) scheme.

2. Discussion of Related Art

Generally, a flash memory has a high voltage transistor and a low voltage transistor for driving cells in view of its device characteristics. A typical method of manufacturing a flash memory device using the SA-STI scheme includes a screen oxide film formation process, a well/threshold voltage ion implantation process, a gate oxide layer formation process (formed in each of a cell region, a high voltage transistor region and a low voltage transistor region), an isolation process, and a gate electrode formation process, all of which are sequentially performed.

Process steps from the formation of a gate oxide film before the formation of a floating gate in a cell region will now be described in more detail.

A semiconductor substrate in which a cell region, a high voltage transistor region and a low voltage transistor region are defined is provided. A high voltage gate oxide layer of about 350 Å in thickness is formed on the semiconductor substrate of the high voltage transistor region through a gate oxide layer formation process. A low voltage gate oxide layer and a cell gate oxide layer are thinly formed in thickness of about 80 Å on the semiconductor substrate of the low voltage transistor region and the cell region. A first polysilicon layer for a floating gate and a nitride layer are then formed on these gate oxide layers. The nitride layer, the first polysilicon layer and the semiconductor substrate are then sequentially etched through an isolation process, thereby forming a number of trenches for isolation. Next, oxide is deposited sufficiently to bury the trenches. A plurality of field oxide films are formed by means of a chemical mechanical polishing (CMP) process. The nitride layer left after the chemical mechanical polishing process is stripped, which exposes the first polysilicon layer between the field oxide films. After the polishing process for removing a native oxide film, etc. is performed, a second polysilicon layer for a floating gate is formed. A floating gate electrode is formed in the cell region by means of an etch process using a mask for a floating gate.

In the above, in order to strip the nitride layer remaining after the CMP process, a H₃PO₄ solution of 120° C. is used. During the process of stripping the nitride layer using the H₃PO₄ solution, phosphorous ions contained in the H₃PO₄ solution are diffused toward the grain boundary of the first polysilicon layer, while the first polysilicon layer is exposed. The phosphorous ions are infiltrated into the gate oxide layers in a subsequent thermal budget process, thus generally degrading gate properties. In particular, as the cell gate oxide layer and the low voltage gate oxide layer are thin in thickness, they are relatively more affected by the infiltrated phosphorous ions than the high voltage gate oxide layer having a thick thickness. Furthermore, the polishing process that is performed before the second polysilicon layer is deposited is performed using a HF cleaner for about 30 seconds. In this case, the first polysilicon layer is exposed to the HF cleaner from the beginning of the polishing process until the end of the polishing process. Due to this, the first polysilicon layer is severely attached by a fluorine radical contained in the HF cleaner. As such, in the conventional method, as the first polysilicon layer is directly exposed to phosphorous ions or fluorine radical, the properties of the gate oxide layer and the gate electrode are degraded. As a result, there are problems that reliability and electrical characteristics of a device are degraded.

### SUMMARY OF THE INVENTION

The present invention is directed to a method of manufacturing a flash memory device that can improve reliability of the device by preventing the properties of a gate oxide layer and a gate electrode from degrading.

According to a preferred embodiment of the present invention, there is provided a method of manufacturing a flash memory device, including the steps of forming a gate oxide layer and a first polysilicon layer on a semiconductor substrate; forming a buffer oxide layer in the first polysilicon layer; forming a nitride layer on the buffer oxide layer; sequentially etching the nitride layer, the buffer oxide layer, the first polysilicon layer, the gate oxide layer and the semiconductor substrate to form a trench for isolation; depositing an oxide layer for isolation on the entire structure including the trench and then polishing the oxide layer for isolation and the nitride layer by a given thickness to form field oxide films within the trench; stripping the nitride layer by means of a nitride strip process; stripping the buffer oxide layer by means of an oxide strip process; and forming a second polysilicon layer on the first polysilicon layer including the field oxide films.

In the above, the semiconductor substrate has a cell region, a high voltage transistor region and a low voltage transistor region defined therein. The gate oxide layer includes a cell gate oxide layer, a high voltage gate oxide layer and a low voltage gate oxide layer. The buffer oxide layer is formed in a thickness of 50 to 150 Å by using an HTO film quality, a MTO film quality or a TEOS film quality. The nitride layer is formed in a thickness of 800 to 1200 Å and remains in a thickness of 600 to 800 Å after the polishing process. The nitride strip process may be performed by setting an etch target so that the buffer oxide layer remains in a thin thickness of 20 to 30 Å, or by setting an etch target to strip the nitride layer without etching the buffer oxide layer. The oxide strip process includes cleaning the surface of the first polysilicon layer while stripping a buffer oxide layer using an HF solution, or stripping the buffer oxide layer using a BOE solution, and then cleaning the first polysilicon layer using the HF solution.

### BRIEF DESCRIPTION OF THE DRAWINGS

FIGS. 1 to 6 are cross-sectional views for explaining a method of manufacturing a flash memory device according to preferred embodiment of the present invention.

### DETAILED DESCRIPTION OF PREFERRED EMBODIMENTS

Now the preferred embodiments according to the present invention will be described with reference to the accompanying drawings. Since preferred embodiments are provided for the purpose that the ordinary skilled in the art are able to understand the present invention, they may be modified in various manners and the scope of the present invention is not limited by the preferred embodiments described later. Further, in the drawing, the thickness and size of each layer are exaggerated for convenience of explanation and clarity. Like reference numerals are used to identify the same or similar parts. Meanwhile, in case where it is described that one film is “on” the other film or a semiconductor substrate, the one film may directly contact the other film or the semiconductor substrate. Or, a third film may be intervened between the one film and the other film or the semiconductor substrate.

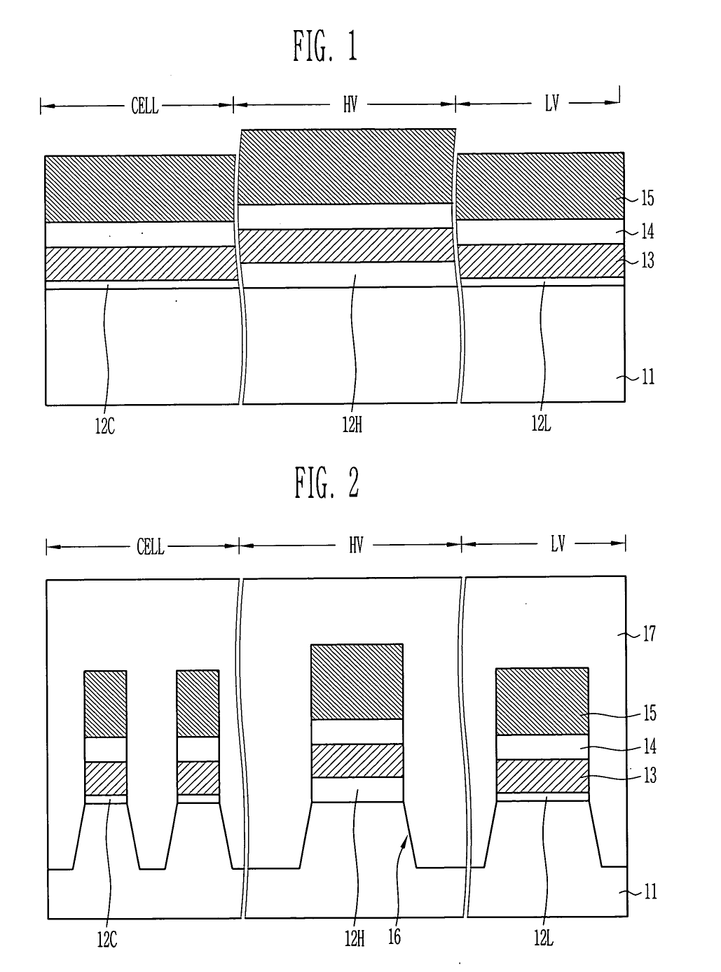

FIGS. 1 to 6 are cross-sectional views for explaining a method of manufacturing a flash memory device according to preferred embodiment of the present invention.

Referring to FIG. 1, a semiconductor substrate 11 in which a cell region CELL, a high voltage transistor region HV and a low voltage transistor region LV are defined is provided. A high voltage gate oxide layer 12H is thickly formed on the semiconductor substrate 11 of the high voltage transistor region HV. A low voltage gate oxide layer 12L and a cell gate oxide layer 12C are thinly formed on the semiconductor substrate 11 of the low voltage transistor region LV and the cell region CELL, respectively. A first polysilicon layer 13 for a floating gate, a buffer oxide layer 14 and a nitride layer 15 are sequentially on the gate oxide layers 12C, 12H and 12L.

In the above, the high voltage gate oxide layer 12H is formed in a thickness of 300 to 500 Å, and each of the low voltage gate oxide layer 12L and the cell gate oxide layer 12C is formed in a thickness of below 100 Å. The first polysilicon layer 13 is formed in a thickness of 300 to 700 Å. The buffer oxide layer 14 is formed in thickness of 50 to 150 A by using a high temperature oxide (HTO) film quality, a middle temperature oxide (MTO) film quality, a tetra ethylene ortho silicate (TEOS) film quality, etc. The HTO film quality employs a SiH₂Cl₂ gas, the MTO film quality employs a SiH₄ gas, and the TEOS film quality employs a Si (OC₂H₅)₄ gas. The nitride layer 15 is formed in a thickness of 800 to 1200 Å.

Referring to FIG. 2, the nitride layer 15, the buffer oxide layer 14, the first polysilicon layer 13, the gate oxide layers 12C, 12H and 12L, and the semiconductor substrate 11 are etched by means of the SA-STI etch process, thereby forming a number of trenches 16 for isolation in the semiconductor substrate 11 of the cell region CELL, the high voltage transistor region HV and the low voltage transistor region LV. An oxide layer 17 for isolation is then formed on the entire structure including the trenches 16 for isolation, whereby the trenches 16 are sufficiently buried.

In the above, the trench 16 is formed in depth of 2500 to 5000 Å. The oxide layer 17 for isolation may be formed using a material having a good insulating property as well as a good gap filing capability, for example, usually HDP oxide. It is, however, to be noted that the oxide layer 17 may be formed in a single layer or a multi-layer structure by using various insulating materials.

By reference to FIG. 3, the oxide layer 17 for isolation and the nitride layer 15 are polished by a given thickness by means of a chemical mechanical polishing (CMP) process, thereby forming field oxide films 170 within the trenches 16. In this case, it may be preferred that the CMP process is performed immediately before the surface of the first polysilicon layer 13 in the high voltage transistor region HV that has a high topology due to the thick high voltage gate oxide layer 12H is exposed. The present invention, however, is not limited to the above. In general, a thickness of the nitride layer 15 remaining in the cell region CELL or the low voltage transistor region LV after the polishing process is in the range of 600 to 800 Å.

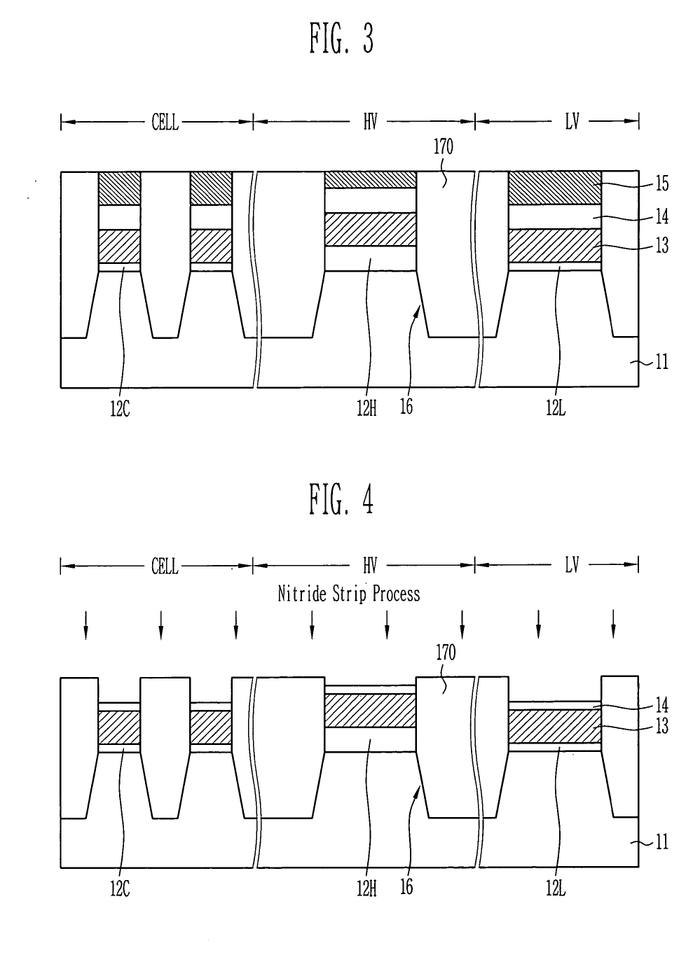

Referring to FIG. 4, a surface treatment process for removing a native oxide film, a metal contaminant, etc. generated on the surface of the nitride layer 15 by using a HF solution or a buffered oxide etchant (BOE) solution, etc. is performed. The remaining nitride layer 15 is then completely stripped by a nitride strip process using an H₃PO₄ solution. The buffer oxide layer 14 is thus exposed.

In the above, the nitride strip process may be performed in two methods.

The first method includes performing a surface treatment process for the remaining nitride layer 15 by using the HF solution or the BOE solution and then using the H₃PO₄ solution to set an etch target so that the buffer oxide layer 14 being an underlying layer of the remaining nitride layer 15 remains in thickness of 20 to 30 Å. Due to this, not only the remaining nitride layer 15 is completely stripped but also the buffer oxide layer 14 remains in thickness of 20 to 30 Å. At this time, the reason why the buffer oxide film 14 remains in thickness of 20 to 30 Å is for the remaining nitride layer 15 to be easily stripped in a pre-cleaning process for 30 seconds using a subsequent HF solution, while preventing the first polysilicon layer 13 from being exposed during the nitride strip process. In general, nitride in the H₃PO₄ solution is etched 40 to 60 Å per minute and oxide in the H₃PO₄ solution is etched 1.5 to 4 Å per minute. It is known that the higher the temperature of the H₃PO₄ solution, the faster the etch rate. In case where a thickness of a nitride layer 15 to be stripped is 600 to 800 Å and a thickness of a buffer oxide layer 14 to be stripped is 30 to 120 Å, a buffer oxide layer 14 of 20 to 30 Å in thickness can be obtained by performing a nitride strip process for about 24 to 34 minutes when a H₃PO₄ solution of 100 to 180° C. is used and for about 34 to 44 minutes when a H₃PO₄ solution of 40 to 100° C. is used. As a result, it is possible to easily form the buffer oxide layer 14 of 20 to 30 Å in thickness by means of the nitride strip process using the H₃PO₄ solution.

The second method includes performing a surface treatment process for the nitride layer 15 left by the HF solution or the BOE solution and then setting an etch target for stripping only the remaining nitride layer 15 by using the H₃PO₄ solution, whereby the buffer oxide layer 14 being an underlying layer remains intact.

Referring to FIG. 5, the exposed buffer oxide layer 14 is completely stripped by an oxide strip process. Thereby, the first polysilicon layer 13 between the field oxide films 17 is exposed.

In the above, the oxide strip process may be performed in two methods depending on a nitride strip process that is previously performed. The first method is to perform an oxide strip process using only the HF solution when the buffer oxide layer 14 remains in thickness of 20 to 30 Å at the time of a nitride strip process. The oxide strip process using the HF solution includes performing a pre-cleaning process, for 30 seconds, which is performed in order to remove a native oxide film, etc. generated on the surface of the first polysilicon layer 13 before a subsequent process for depositing a second polysilicon layer for a floating gate. At this time, it is known that oxide in the HF solution is etched in a thickness of 1 Å per second. For this reason, during the pre-cleaning process for about 30 seconds, the buffer oxide layer 14 of 20 to 30 Å in a thickness is completely stripped. The second method includes stripping the buffer oxide layer 14 to expose the first polysilicon layer 13, by using a buffered oxide etchant (BOE) solution in which NH₄F and HF are adequately mixed, for example, in the ratio of 9:1, 100:1 or 300:1, when the buffer oxide layer 14 is etched during the nitride strip process but has a firstly deposited thickness, and then performing a pre-cleaning process for about 30 seconds using the HF solution.

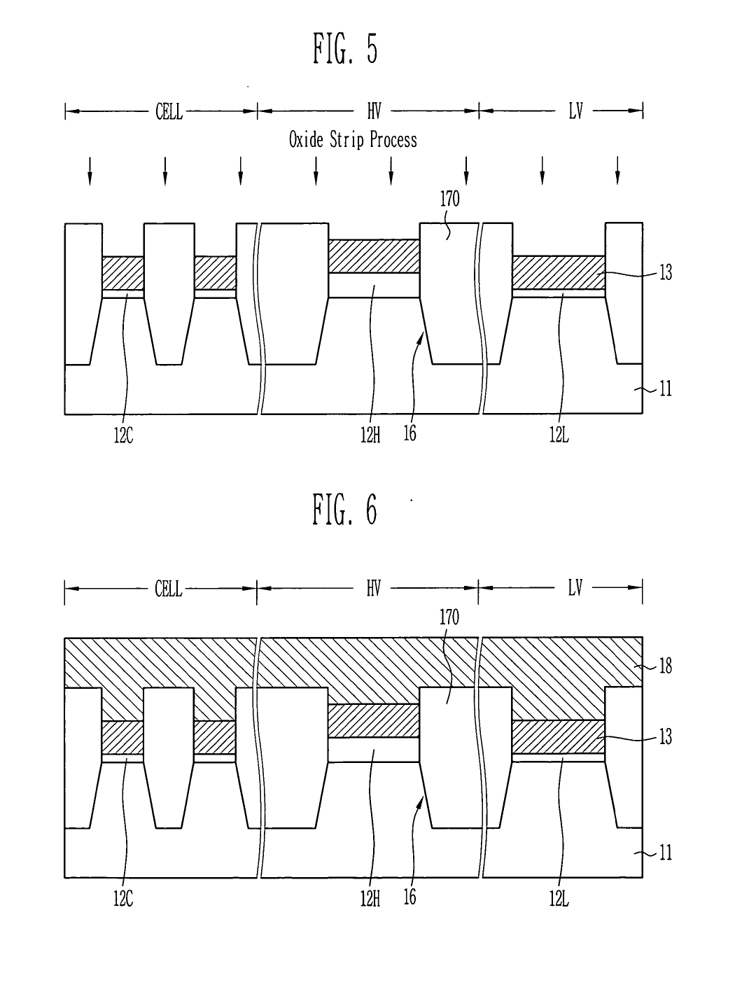

By reference to FIG. 6, a second polysilicon layer 18 for a floating gate is formed on the entire structure including the field oxide films 170 and the first polysilicon layer 13. Though not shown in the drawings, an etch process using a mask for a floating gate, a dielectric layer formation layer, a process of forming a conductive layer for a control gate, and an etch process using a mask for a control gate are then performed to form gates in respective regions.

According to the present invention described above, in a flash memory device using a self-aligned shallow trench isolation scheme, a buffer oxide layer is formed between a first polysilicon layer and a nitride layer. After a polishing process for forming a field oxide film is performed, a buffer oxide layer is used as an etch-prevention layer in the process of stripping the nitride layer and the buffer oxide layer is stripped in a cleaning process before a second polysilicon layer is deposited. It is thus possible not only to prevent phosphorous ions contained in an H₃PO₄ solution used in the process of stripping the nitride layer from diffusing into the grain boundary of the first polysilicon layer, but also to reduce the time when the first polysilicon layer is exposed to a HF cleaner used in the cleaning process before the second polysilicon layer is deposited. Therefore, the present invention has effects that it can enhance the properties of a gate oxide layer and a gate electrode by minimizing an attack of fluorine radical contained in the HF cleaner against the first polysilicon layer.

Although the foregoing description has been made with reference to the preferred embodiments, it is to be understood that changes and modifications of the present invention may be made by the ordinary skilled in the art without departing from the spirit and scope of the present invention and appended claims.

1. A method of manufacturing a flash memory device, comprising the steps of:
forming a gate oxide layer and a first polysilicon layer on a semiconductor substrate;
forming a buffer oxide layer in the first polysilicon layer;
forming a nitride layer on the buffer oxide layer and then sequentially etching the nitride layer, the buffer oxide layer, the first polysilicon layer, the gate oxide layer and the semiconductor substrate to form a trench for isolation;
depositing an oxide layer for isolation on the entire structure including the trench and then polishing the oxide layer for isolation and the nitride layer by a given thickness to form field oxide films within the trench;
stripping the nitride layer by means of a nitride strip process;
stripping the buffer oxide layer by means of an oxide strip process; and
forming a second polysilicon layer on the first polysilicon layer including the field oxide films.

2. The method as claimed in claim 1, wherein the semiconductor substrate has a cell region, a high voltage transistor region and a low voltage transistor region defined therein.

3. The method as claimed in claim 1, wherein the gate oxide layer includes a cell gate oxide layer, a high voltage gate oxide layer and a low voltage gate oxide layer.

4. The method as claimed in claim 1, wherein the buffer oxide layer is formed in a thickness of 50 Å to 150 Å by using an HTO film quality, an MTO film quality or a TEOS film quality.

5. The method as claimed in claim 1, wherein the nitride layer is formed in a thickness of 800 Å to 1200 Å and remains in a thickness of 600 Å to 800 Å after the polishing process.

6. The method as claimed in claim 1, wherein the nitride strip process is performed by setting an etch target so that the buffer oxide layer remains in a thin thickness of 20 Å to 30 Å and the oxide strip process is performed by using an HF solution.

7. The method as claimed in claim 6, wherein the nitride strip process is performed in an H₃PO₄ solution of 100° C. to 180° C. for 24 to 34 minutes, if a thickness of the nitride layer to be stripped is 600 Å to 800 Å and a thickness of the buffer oxide layer to be stripped is 30 Å to 120 Å.

8. The method as claimed in claim 6, wherein the nitride strip process is performed in an H₃PO₄ solution of 40° C. to 100° C. for 34 to 44 minutes, if a thickness of the nitride layer to be stripped is 600 Å to 800 Å and a thickness of the buffer oxide layer to be stripped is 30 Å to 120 Å.

9. The method as claimed in claim 6, wherein the oxide strip process is performed for about 30 seconds to clean the surface of the first polysilicon layer, while stripping the buffer oxide layer of the thin thickness.

10. The method as claimed in claim 1, wherein the nitride strip process is performed by setting an etch target to strip the nitride layer without etching the buffer oxide layer and the oxide strip process is performed by using sequentially a BOE solution and an HF solution.

11. The method as claimed in claim 10, wherein the oxide strip process includes stripping the buffer oxide layer by using the BOE solution and cleaning the first polysilicon layer by using the HF solution for 30 seconds.

12. The method as claimed in claim 11, wherein the BOE solution has NH₄F and HF mixed in the ratio of 9:1, 100:1 or 300:1.
